(19) United States
(12) Patent Application Publication
(10) Pub. No.: US 2025/0285234 A1
(43) Pub. Date: Sep. 11, 2025

(54) Image Reconstruction in Magnetic Resonance Imaging

(71) Applicant: Siemens Healthineers AG, Forchheim (DE)

(72) Inventors: Marc Vornehm, Erlangen (DE); Florian Fürnrohr, Harburg (Schwaben) (DE); Jens Wetzl, Erlangen (DE); Daniel Giese, Erlangen (DE); Florian Knoll, Erlangen (DE)

(73) Assignee: Siemens Healthineers AG, Forchheim (DE)

(21) Appl. No.: 19/071,973

(22) Filed: Mar. 6, 2025

(30) Foreign Application Priority Data
Mar. 6, 2024 (DE) 10 2024 202 100.8

(51) Int. Cl. G06T 5/60; G01R 33/56; G06T 5/10; G06T 11/00

(52) U.S. Cl. CPC G06T 5/60; G01R 33/5608; G06T 5/10; G06T 11/006; G06T 2207/20081; G06T 2207/20084; G06T 2210/41

(57) ABSTRACT

For image reconstruction in magnetic resonance (MR) imaging MR measurement data, which represents an imaged object, is obtained and refined MR data is created by a refinement module of a trained MLM (machine learning model) being applied to module input data dependent on the MR measurement data. An image reconstruction is created depending on the refined MR data, wherein: i) optimized MR data is created depending on the MR measurement data in that, by variation of variable image data, a predefined target function is optimized, and the module input data depends on the optimized MR data; and/or ii) further optimized MR data is created depending on the refined MR data in that, by variation of variable image data, a further target function is optimized, and the image reconstruction is created depending on the further optimized MR data.

### BACKGROUND

The aspects of the disclosure relate to a computer-implemented method for image reconstruction in magnetic resonance imaging, wherein MR measurement data that represents an imaged object is obtained, refined MR data is created by a refinement module of a trained machine learning model MLM being applied to the module input data depending on the MR measurement data and an image reconstruction depending on the refined MR data is created. The aspects of the disclosure further relate to a computer-implemented training method for training an MLM for use in such a computer-implemented method for image reconstruction in magnetic resonance imaging, to a data processing system for carrying out such a computer-implemented method or to such a computer-implemented training method, as well as to corresponding computer program products.

The term image refers here and below to the local space, which is also called the image space or image domain unless stated otherwise. In MR imaging image reconstruction refers to the process of creating a two-dimensional image or a three-dimensional image, typically in the form of a number of two-dimensional images, for a number of positions along the so-called slice direction in the image space from the measurement data depending on the MR signals that are emitted by an object to be imaged detected in the k-space.

In general, the k-space and the image space are linked to one another by way of a Fourier transform. In parallel MR imaging, also referred to as accelerated MR imaging, the MR measurement data is received by a number of receive coils, which receive the MR signals emitted. What is more, techniques for undersampling of the k-space can be employed, in which the k-space is sampled with a sampling rate that is too low to fulfill the Nyquist criterion. The latter is also referred to an incomplete sampling. The number of coils, or the data provided by them, are referred to as coil channels or receive coil channels. The image reconstruction can therefore not be obtained solely by a Fourier transform of the detected MR measurement data. Instead, more complex reconstruction techniques are used. Various methods for MR image reconstruction are known, which can include iterative processes and/or optimizations based on physical relationships for example.

Application-specific parameters can be considered in MR image reconstruction. These parameters can stem from various physical interrelationships, depending on the respective application. The parameters can for example be associated with the movement of an object to be imaged during data acquisition, the specific underlying sampling pattern in the k-space and so forth.

What is more, trained machine learning models, MLM, for example artificial neural networks (ANN), in particular convolutional neural networks (CNN), can be used for MR image reconstruction, for example in combination with conventional reconstruction approaches. The term “conventional” relates in this case to the state of affairs in which an MLM is not involved. For example, such methods are sometimes referred to as deep learning, DL, reconstructions. An overview of the topic is provided by the publication by G. Zeng et al: “A review on deep learning MRI reconstruction without fully sampled k-space”, BMC Med Imaging 21, 195 (2021).

In the publications by K. Hammernik et al.: “Learning a variational network for reconstruction of accelerated MRI data.”, Magn. Reson. Med., 18, 79 (6), 3055-3071 and A. Sriram et al.: “End-to-End Variational Networks for Accelerated MRI Reconstruction”, in A. Martel et al.: “Medical Image Computing and Computer Assisted Intervention”, MICCAI20, Vol, 12262, Lecture Notes in Computer Science. Cham: Springer International Publishing, 20, 4-73, an ANN architecture referred to below as a variation network, which uses an iterative steepest gradient descent approach is used to solve the problem of MR image reconstruction. The number of iterations, which are also referred to as cascades, is predetermined here and, in the minimum limit case, can also be equal to one. The variation network implements operations that aim to establish consistency with the MR measurement data, also referred to as data consistency, in that in each iteration a weighted average value of the MR measurement data and the current reconstruction estimate is calculated, wherein the weighting is a learned parameter. It should be pointed out however that this operation does not always correctly ensure data consistency, which leads to suboptimal reconstructions.

U-Net, described in publications by O. Ronneberger et al: “U-Net: Convolutional Networks for Biomedical Image Segmentation” (arXiv: 1505.04597v1), is a known CNN, which can be employed for example for segmentation of images or for image refinement.

### SUMMARY

An object of the present aspects of the disclosure is to improve the quality of an image reconstruction in magnetic resonance imaging by DL reconstruction methods, MR imaging.

This object is achieved by the respective subject matter of the independent claims. Advantageous developments and preferred forms of aspect are the subject matter of the dependent claims.

The aspects of the disclosure are based on the idea, before and/or after the application of a trained machine learning model, MLM, of optimizing the MR measurement data and/or the current MR data of an iteration within the framework of image reconstruction in MR imaging.

In accordance with one aspect of the disclosure a computer-implemented method for image reconstruction in MR imaging is specified. In this method MR measurement data that represents an imaged object is obtained and refined MR data is created by a refinement module of a trained MLM being applied to the module input data depending on the MR measurement data. An image reconstruction is created depending on the refined MR data.

In this case, i) depending on the MR measurement data, optimized MR data is created by a predefined target function being optimized by variation of variable image data and the module input data depends on the optimized MR data. As an alternative or in addition, ii) further optimized MR data is created depending on the refined MR data by a further target function being optimized by variation of variable image data and by the image reconstruction being created depending on the further optimized MR data.

Unless stated otherwise, all steps of the computer-implemented method can be carried out by a data processing system that includes at least one data processing device. In particular the at least one data processing device is configured or adapted for carrying out the steps of the computer-implemented method. For this purpose, the at least one data processing device can for example store a computer program that includes commands, which, when they are executed by the at least one data processing device, cause the at least one data processing device to carry out the computer-implemented method. The computer-implemented method can also be implemented entirely or partly in hardware. The expressions “data processing system” and “at least one data processing device” can be used interchangeably here and below. This also applies to corresponding expressions derived therefrom.

For the case in which the at least one data processing device includes two or more data processing devices, specific steps performed by the at least one data processing device can also be understood as various data processing devices carrying out various steps or various parts of a step. In particular it is not necessary for each data processing device to carry out the steps. In other words, the performance of the step can be divided between the two or more data processing devices.

Obtaining the MR measurement data can for example include an acquisition and/or reading out of a computer-readable data memory and/or a receipt from a data memory unit, for example from a database, and/or a receipt of a data stream with the first dataset, for example from an MR system.

Each form of aspects of the disclosure of the computer-implemented method produces a corresponding form of aspect of a method for image reconstruction in MR imaging that is not purely computer-implemented, in that corresponding steps for creation of the MR measurement data, in particular by means of the MR system, are included. In such forms of aspects of the disclosure, the creation of the MR measurement data can comprise an acquisition or recording, in particular measuring, of the MR measurement data by means of the MR system.

Expressed in general terms a trained MLM can emulate cognitive functions, which make a connection between humans and another human understanding. In particular the MLM, through training based on training data, can be capable of adapting itself to new circumstances and of detecting and extrapolating new patterns. Another term for a trained MLM is “trained function”.

In general, the parameters of an MLM can be adapted or updated by training. In this case in particular supervised training, semi-supervised training, unsupervised training, reinforcement learning and/or active learning can be employed. What is more representation learning, which is also referred to as feature learning, can be used. In particular the parameters of the MLMs can be adapted iteratively by a number of steps of the training. In particular during training a specific loss function, which is also referred to as a cost function, can be minimized. The backpropagation algorithm can be used in particular during training of an ANN.

An MLM can in particular include an ANN, a support vector machine, a decision tree and/or a Bayesian network, and/or the MLM can be based on k-means clustering, Q learning, genetic algorithms and/or association rules. In particular an ANN can be or can include a deep neural network, a convolutional neural network (CNN) or a convolutional deep neural network. Moreover, an ANN can be an adversarial network, a deep adversarial network and/or a generative adversarial network. The MLM can in particular be a variation network as described at the outset, or can be based thereon. The optimization of the target function can be integrated into the MLM for example or be placed before the MLM. The optimization of the further target function can be integrated into the MLM or be placed after the MLM for example.

The MR measurement data is in particular data in the k-space, which is created by means of one or a number of receive coils of the MR system in accordance with a k-space sampling scheme, in particular an incomplete sampling scheme.

The creation of the image reconstruction depending on the refined MR data, or on the further optimized MR data, is undertaken in particular using method steps known for this purpose. For example, a predetermined conjugate forward encoding operator can be applied to the refined MR data or to data dependent thereon or to the further optimized MR data or data dependent thereon. The forward encoding operator is also referred to by E and the conjugate forward encoding operator E^{H} then corresponds for example to the Hermitian conjugate of the forward encoding operator. The forward encoding operator consists in particular of a Fourier transform and, in the case of a number of receive coil channels, to the receive coils assigned to the corresponding coil sensitivity profiles of the receive coil channels. In some conventions the forward encoding operator also includes a masking operator M corresponding to the k-space sampling scheme used, which causes non-sampled points in the k-space to be hidden, i.e. masked to a certain extent. Here and below the masking operator will however be considered separately from the forward encoding operator and is not an element of the same.

In forms of aspect in accordance with case i), the target function depends in particular explicitly on the variable image data x. In forms of aspect in accordance with case ii), the further target function depends in particular explicitly on the variable image data x and the refined MR data kₙ, for example on x−xₙ=x−E^{H} kₙ.

The optimization of the target function and/or of the further target function can be undertaken with the aid of known optimization techniques, in particular differentiable optimization techniques, for example with optimizations in accordance with gradient-based techniques or the like. The optimization can in particular be carried out iteratively. For example, the optimization of the target function and/or of the further target function can be carried out using a method of conjugate gradients, also known as the CG method.

The variable image data can be understood as the respective optimization variables of the optimization of the target function or of the further target function. The optimal variable image data as a result of the optimization of the target function corresponds to the optimized MR data. The optimal variable image data as a result of the optimization of the further target function corresponds to the further optimized MR data. The target function and/or the further target function can for example be predetermined in such a way that they place deviations of the variable image data from the MR measurement data at a disadvantage and that data consistency over the optimization path is rewarded.

The disclosed optimization of the target function and/or of the further target function enables data consistency in the reconstruction to be improved with the help of the trained MLM, which enhances the quality of the image reconstruction. It should be emphasized in this case that that the computer-implemented method for image reconstruction in MR reconstruction corresponds to a usage phase, also as an inference phase, of the already previously trained MLM. The optimization of the target function and/or the further target function thus does not serve for the training of the MLM, but for the actual image reconstruction based on the MR measurement data.

In accordance with at least one form of aspect the refinement module includes an ANN, in particular a CNN.

The ANN or the CNN is in particular an image-to-image ANN. A U-Net, in particular a U-Net with 3D convolution layers, can be used for example.

The disclosed method has previously been described with the aid of a single stage, also referred to as a cascade, of the MLM, which contains the refinement module and for example an optimization module that carries out the optimization of the target function, and/or a further optimization module that carries out the optimization of the further target function. Although the optimization module and the further optimization module do not necessarily include trainable or trained parameters, these are regarded here and in what follows as part of the MLM. In some forms of aspects of the disclosure, the optimization module and/or the further optimization module can however also include trainable or trained parameters.

In various forms of aspects of the disclosure, the MLM has two or more stages however, wherein one stage of the two or more stages contains the refinement module. The MLM contains an optimization module, which is adapted, depending on the MR measurement data, to create the optimized MR data and, by variation of the variable image data, to optimize the target function and/or the MLM contains a further optimization module, which is adapted, depending on the refined MR data, to create the further optimized MR data and, by variation of the variable image data, to optimize the further target function.

Each stage of the two or more stages contains a refinement module that is structured as described above and has the functionality described. The architecture of all refinement modules of the two or more stages can be identical, however the individual trained parameters of the refinement modules of the two or more stages can differ from one another despite this. The reader is referred in this context to the variation network of the publications cited at the outset, which accordingly can be constructed from a number of stages.

Each stage of the two or more stages can include an optimization module, which precedes the respective refinement module, or a further optimization module, which follows the respective refinement module. The optimization module of one stage can then, depending on nomenclature, also be expressed as the further optimization module of the preceding stage or the further optimization module of one stage can be expressed as the optimization module of the following stage. Thus, for example in each stage an optimization module can be provided before the refinement module or a further optimization module after the refinement module. Also, in each stage an optimization module can be provided before the refinement module and in addition a further optimization module after the refinement module after a final stage of the two or more stages. A further optimization module can also be provided after the refinement module in each stage and in addition an optimization module before the refinement module before an initial stage of the two or more stages.

It is also possible for the MLM to have precisely one optimization module before the refinement module of the initial stage or precisely one further optimization module after the refinement module of the final stage. All mixed forms are also possible, so that with a total of T stages the overall number N of the optimization modules and further optimization modules can lie between 1 and T+1.

In this way a suitable compromise between especially high quality of the image reconstruction and computing effort for optimization can be found, by the number of and/or positions of the optimization modules and further optimization modules being adapted.

The explanations given below can also be transferred accordingly to the various stages, insofar as two or more stages are provided.

In accordance with at least one form of aspect the application of the refinement module to the module input data includes a transformation of the module input data from the k-space into the image space and an application of the CNN to the transformed module input data.

In such forms of aspects of the disclosure, the high performance of known CNN architectures for processing of images in the image space can be utilized. Where necessary, correspondingly pretrained, in particular more or less generically pretrained, CNNs can also be used without any complex training based on k-space data being required. The transformation into the image space can be undertaken for example by application of the forward conjugate encoding operator.

In accordance with at least one form of aspect the refined MR data is determined as a function of a sum or weighted sum of the output of the CNN and of a data consistency term. The data consistency term depends on a deviation of the module input data from the MR measurement data, in particular on a difference between the module input data and the MR measurement data, for example on an L2 norm of the difference.

In this way, in particular in combination with the optimization of the target function and/or the optimization of the further target function, a high measure of data consistency is able to be achieved. The refined MR data can be determined for example as a function of the data consistency term and a weighted average value of the back-transformed output of the CNN and of the MR measurement data.

In accordance with at least one form of aspect the application of the refinement module to the module input data includes a transformation of the module input data from the k-space into the image space and an application of the CNN to the transformed module input data and a back-transformation of an output of the CNN into the k-space.

In such forms of aspects of the disclosure, the high performance of known CNN architectures for processing of images in the image space can likewise be utilized. The back-transformation into the k-space can be undertaken for example by application of the forward encoding operator.

In accordance with at least one form of aspect the refined MR data is determined as a function of a sum or weighted sum of the back-transformed output of the CNN and of a data consistency term. The data consistency term depends on a deviation of the module input data from the MR measurement data, in particular on a difference between the module input data and the MR measurement data, for example on an L2 norm of the difference.

In this way, in particular in combination with the optimization of the target function and/or the optimization of the further target function, a high measure of data consistency is able to be achieved. The refined MR data can be determined for example as function of the data consistency term and a weighted average value of the back-transformed output of the CNN and of the MR measurement data.

In accordance with at least one form of aspect the target function is given by

$${‖ MEx - {k}_{0} ‖}_{2}^{2} + {μ}_{0} {‖ x ‖}_{2}^{2} ,$$

wherein x refers to the variable image data, E refers to the forward encoding operator, M refers to the masking operator corresponding to the k-space sampling schemas used when creating the MR measurement data, and μ₀ refers to a predetermined regularization parameter. ∥ ∥₂ refers in particular to the L2 norm.

Instead of the L2 norm, in other forms of aspect other functions or transformations of x can also be used however, for example the L1 norm, an L1 wavelet regularization, a TV regularization (TV stands for total variation), and so forth. In L1 wavelet regularization for example the L1 norm of a wavelet transformation of x is used instead of the said L2 norm of x.

In this way what is achieved on the one hand, in particular by the first term of the target function, is that in the optimization of the target function an especially high data consistency is achieved and, in particular by the second term of the target function, a regularization is achieved.

The regularization parameter μ₀, can, in some forms of aspect, be a trained parameter, i.e. defined by the training of the MLM. As an alternative the regularization parameter μ₀ can also be determined by trial and error and/or with the aid of empirical values.

In accordance with at least one form of aspect the further target function depends on a deviation, in particular difference, for example L2 norm of the difference, between variable image data and refined image data. The refined image data is given by

xₙ=E^{H}kₙ,

wherein kₙ refers to the refined MR data and E^{H} refers to the conjugate forward encoding operator.

In this way in particular, even in the case of parallel MR imaging, an especially high quality of the image reconstruction can be achieved.

In accordance with at least one form of aspect the further target function is given by

$${‖ MEx - {k}_{0} ‖}_{2}^{2} + {μ}_{n} {‖ x - {x}_{n} ‖}_{2}^{2} ,$$

wherein x refers to the variable image data, E refers to the forward encoding operator, M refers to the masking operator corresponding to the k-space sampling schemas used for creating the MR measurement data and μₙ refers to a predetermined regularization parameter. ∥ ∥₂ refers in particular to the L2 norm. Instead of the L2 norm, in other forms of aspect other functions of x−xₙ can also be used however, for example the L1 norm or the like.

In this way what is achieved on the one hand, in particular by the first term of the target function, is that in the optimization of the target function an especially high data consistency is achieved, as well as in particular by the second term of the target function, that an especially low deviation from the refined image data is achieved.

The regularization parameter μₙ, in some forms of aspect, can be a trainable parameter, i.e. defined by the training of the MLM. As an alternative the regularization parameter Un can also be determined by trial and error and/or with the aid of empirical values.

In accordance with at least one form of aspect the MR measurement data corresponds to data that has been measured in accordance with at least two receive coil channels.

In other words, the MR measurement data is acquired by use of an accelerated or parallel MR data acquisition method. The aspects of the disclosure are especially advantageous here since the resulting structure of the forward encoding operator, depending on the coil sensitivities, leads to the DL reconstruction being especially advantageous and accordingly to the quality enhancement of the image reconstruction being especially important.

In accordance with a further aspect of the disclosure an MR imaging method is specified. In this method MR measurement data, which represents an imaged object, is created, in particular by an MR system. Then, based on the MR measurement data, a disclosed computer-implemented method for image reconstruction in MR imaging is carried out.

In accordance with a further aspect of the disclosure a computer-implemented training method for training an MLM, which is an ANN for example, is specified for use in a disclosed computer-implemented method for image reconstruction in MR imaging. In this method MR training data is obtained. Refined MR training data is created by a refinement module of the MLM being applied to module training input data dependent on the MR training data. A predetermined loss function is evaluated depending on the MR training data and the refined MR training data, and the MLM is updated depending on a result of the evaluation of the loss function.

In this case, depending on the MR training data, optimized MR training data is created, in that, by variation of variable image data, the target function is optimized, and the module training input data depends on the optimized MR training data and/or further optimized MR training data is created depending on the refined MR training data, in that, by variation of variable image data, the further target function is optimized, and the loss function depends on the further optimized MR training data.

Unless stated otherwise, all steps of the computer-implemented training method can be carried out by a further data processing system, which includes at least one further data processing device. In particular the at least one further data processing device is configured or adapted to carry out the steps of the computer-implemented training method. For this purpose, the at least one further data processing device can for example store a further computer program, which includes commands that, when they are executed by the at least one further data processing device, cause the at least one further data processing device to carry out the computer-implemented training method. The computer-implemented training method can also be implemented entirely or partly in hardware.

For the case in which the at least one further data processing device includes two or more further data processing devices, specific steps carried out by the at least one further data processing device can also be understood such that various further data processing devices carry out various steps or various parts of a step. In particular there is no requirement for each further data processing device to carry out the steps. In other words, the carrying out of the steps can be distributed between two or more further data processing devices.

Obtaining the MR training data can for example include an acquisition and/or reading out of a computer-readable data memory and/or a receipt from a data memory unit, for example from a database, and/or a receipt of a data stream with the first dataset, for example from the MR system.

Each form of aspect of the computer-implemented method produces a corresponding form of aspect of a method for image reconstruction in MR imaging that is not purely computer-implemented, in that corresponding steps for creating the MR measurement data, in particular by means of the MR system, are incorporated. In such forms of aspects of the disclosure, the creation of the MR measurement data can comprise an acquisition or recording, in particular measuring, of the MR measurement data by means of the MR system.

The updating of the MLM depending on the result of the evaluation of the loss function can for example, in the case of an ANN as the MLM, include the updating of corresponding weights of the ANN.

In forms of aspect in which the MLM, as described above, has a number of stages, the number of stages, in particular their refinement modules and where necessary other trainable parameters, can be trained together, i.e. end-to-end.

In accordance with at least one form of aspect a training image reconstruction is be created depending on the refined MR training data and the loss function depends on the training image reconstruction.

In accordance with at least one form of aspect the further optimized MR training data is created depending on the refined MR training data, in that by variation of variable image data, the further target function is optimized, and the loss function depends on the further optimized MR training data. The training image reconstruction is created depending on the further optimized MR training data.

In accordance with at least one form of aspect completely sampled MR data is obtained and the MR training data is created depending on the completely sampled MR data in accordance with a predetermined undersampling scheme. A ground truth image reconstruction is created based on the completely sampled MR data and the loss function depends on a deviation between the training image reconstruction and the ground truth image reconstruction.

In particular the MLM is thus trained based on retrospectively undersampled MR data, in particular trained in a supervised manner. This is especially advantageous since the ground truth image reconstruction can then be created in a simple way, in particular without a corresponding masking operator being required.

In accordance with at least one form of aspect the MR training data corresponds to undersampled MR data in accordance with a predetermined undersampling scheme and the MLM is trained by self-supervised learning.

This is especially advantageous, since then a ground truth image reconstruction does not have to be created manually or separately on its own.

In accordance with at least one form of aspect of the disclosed computer-implemented method for image reconstruction in MR imaging the MLM is or has been trained by a disclosed computer-implemented training method.

In some forms of aspect of the disclosed computer-implemented method for image reconstruction in MR imaging the steps of the disclosed computer-implemented training method can be part of the computer-implemented method for image reconstruction in MR imaging.

In accordance with a further aspect of the disclosure a data processing system is specified. The data processing system has at least one data processing device, which is adapted to carry out a disclosed computer-implemented method for image reconstruction.

In accordance with a further aspect of the disclosure a further data processing system is specified. The further data processing system has at least one further data processing device, which is adapted to carry out a disclosed computer-implemented training method.

In the present publication the expressions “data processing system” and “at least one data processing device” can be used interchangeably. A data processing device can be understood in particular as a data processing device that contains a processing circuit. The data processing device can thus in particular process data for carrying out computing operations. Where necessary these also include operations for carrying out indexed accesses to a data structure, for example a look-up table (LUT), as well as a data processing process implemented in hardware.

The data processing device can in particular contain one or more computers, one or more microcontrollers and/or one or more integrated circuits, for example one or more application-specific integrated circuits (ASIC), one or more field-programmable gate arrays (FPGA), and/or one or more systems on a chip (SoC). The data processing device can also comprise one or more processors, for example one or more microprocessors, one or more central processing units (CPU), one or more graphics processing units (GPU) and/or one or more signal processors, in particular one or more digital signal processors (DSP). The data processing device can also include a physical or a virtual network of computers or others of the said units.

In various exemplary aspects the data processing device includes one or more hardware and/or software interfaces and/or one or more memory units.

A memory unit can be embodied as a volatile data memory, for example as a dynamic random access memory (DRAM) or static random access memory (SRAM), or as a non-volatile data memory, for example as a read-only memory (ROM), as a programmable read-only memory (PROM), as an erasable programmable read-only memory (EPROM), as an electrically erasable programmable read-only memory (EEPROM), as a flash memory or flash EEPROM, as a ferroelectric random access memory (FRAM), as a magnetoresistive random access memory (MRAM) or as a phase-change random access memory (PCRAM).

In accordance with a further aspect of the disclosure an MR system is specified. The MR system has an MR scanner which is configured to create MR measurement data that represents an imaged object. The MR system further comprises at least one data processing device, which is adapted to carry out a disclosed computer-implemented method for image reconstruction.

In accordance with a further aspect of the disclosure a computer program with commands is specified. When the commands are executed by the at least one data processing device, the commands cause the at least one data processing device to carry out a disclosed computer-implemented method for image reconstruction.

In accordance with a further aspect of the disclosure a further computer program with further commands is specified. When the further commands are executed by the at least one further data processing device, the further commands cause the at least one further data processing device to carry out a disclosed computer-implemented training method.

The commands and/or the further commands can be present for example as program code. The program code can for example be provided as binary code or Assembler and/or as source code of a programing language, for example C, and/or as a program script, for example Python.

In accordance with a further aspect of the disclosure a computer-readable memory medium is specified that stores a disclosed computer program and/or a disclosed further computer program.

The computer program, the further computer program and the computer-readable memory medium are each computer program products with the commands or the further commands.

The disclosed solution is described above and in what follows both in respect of the claimed systems and also in respect of the claimed methods. Features, advantages or alternate forms of aspect can be assigned to the other claimed subject matter and vice versa. In other words, the claims and forms of aspect for the systems can be improved by features that are described or claimed in conjunction with the respective methods. In this case the functional features of the method are implemented by physical units of the system.

What is more, the disclosed solution is described above and in what follows with respect to methods and systems for MR image reconstruction as well as with respect to methods and systems for provision of a trained MLM. Features, advantages or alternate forms of aspect can be assigned to the other claimed subject matter and vice versa. In other words, claims and forms of aspect for provision of a trained MLM can be improved with features that are described or claimed in conjunction with the MR image reconstruction. In particular the datasets used in the methods and systems can have the same properties and features as the corresponding datasets that are used in the methods and systems for provision of a trained MLM, and the trained MLM provided by the respective methods and systems can be used in the methods and systems for MR image reconstruction.

Further features and combinations of features of the disclosure emerge from the figures and their description, and also from the claims. In particular further forms of aspect of the disclosure do not absolutely have to contain all features of one of the claims. Further forms of aspect of the disclosures can have features or combinations of features that are not given in the claims.

The aspects of the disclosure will be explained in greater detail below with the aid of concrete exemplary aspects and associated schematic drawings. In the figures the same elements or elements that have the same function can be labeled with the same reference characters. The description of elements that are the same or have the same function is where necessary not repeated in relation to different figures.

### DESCRIPTION OF THE DRAWINGS

In the figures:

FIG. 1 shows a schematic diagram of an exemplary form of aspect of a disclosed MR system;

FIG. 2 shows a schematic block diagram of an exemplary form of aspect of a disclosed computer-implemented method for image reconstruction in MR imaging;

FIG. 3 shows a schematic block diagram of a further exemplary form of aspect of a disclosed computer-implemented method for image reconstruction in MR imaging;

FIG. 4 shows a schematic block diagram of a further exemplary form of aspect of a disclosed computer-implemented method for image reconstruction in MR imaging;

FIG. 5 shows a schematic block diagram of a further exemplary form of aspect of a disclosed computer-implemented method for image reconstruction in MR imaging;

FIG. 6 shows a schematic block diagram of a refinement module in a further exemplary form of aspect of a disclosed computer-implemented method for image reconstruction in MR imaging;

FIG. 7 shows a schematic block diagram of a further exemplary form of aspect of a disclosed computer-implemented method for image reconstruction in MR imaging;

FIG. 8 shows a schematic diagram of an artificial neural network;

FIG. 9 shows a schematic diagram of a convolutional neural network; and

FIG. 10 shows a schematic diagram of a further convolutional neural network.

### DETAILED DESCRIPTION

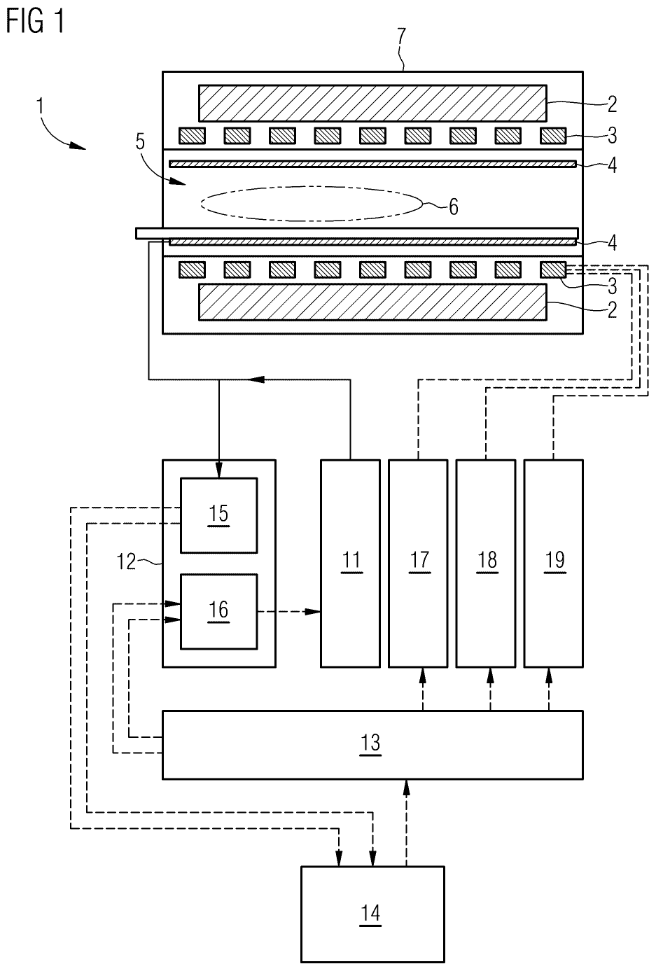

FIG. 1 shows a schematic diagram of an exemplary form of aspect of an MR system 1 in accordance with the disclosure. The MR system 1 has a housing 7 that defines a bore 5 and a main magnet arrangement 2, which is configured to create a main magnetic field, also called a polarizing magnetic field, within the bore 5. The MR system 1 includes an RF system 4, 11, 12, which is configured to apply RF pulses to a target material arranged in the bore 5, in particular to a part of the body of a patient, and to receive MR signals emitted by the target material. For example, the main magnet arrangement 2 can create a uniform main magnetic field B0 as the main magnetic field and at least one RF coil 4 of the RF system 4, 11, 12 can emit an excitation field B1. The MR system 1 includes a data processing system 14 with at least one data processing device, which is configured to carry out a computer-implemented method for image reconstruction in MR imaging in accordance with the present disclosure.

In accordance with MR techniques the target material is exposed to the main magnetic field, whereby a precession of the nuclear spins with their characteristic Larmor frequency about the direction of the main magnetic field is brought about in the target material. In the direction z of the main magnetic field a magnetic net moment Mz is created, and the randomly oriented magnetic moments of the nuclear spins mutually cancel each other out in the x-y plane.

When the target material is then exposed to the emitted RF magnetic field, which lies for example in the x-y plane and close to the Larmor frequency, the magnetic net moment rotates out of the z direction and creates a magnetic net moment in the plane of which the projection in the x-y plane rotates with the Larmor frequency. As a reaction to this, MR signals are emitted by the excited spins, when they return to their state before the excitation. The emitted MR signals are detected for example by the at least one RF coil 4 and/or by one or more dedicated detection coils, digitized in a receive channel 15 of an RF controller 12 of the RF system 4, 11, 12 and processed by the data processing system 14 in order to reconstruct an MR image using the disclosed computer-implemented method.

In particular the gradient coils 3 of the MR system 1 can create magnetic field gradients Gx, Gy and Gz for position encoding of the MR signals. Accordingly, MR signals are only emitted by such nuclei of the target material that correspond to the respective Larmor frequency. For example, Gz is used together with a bandwidth-limited RF pulse in order to select a slice perpendicular to the z direction and can therefore also be referred to as the slice selection gradient. In another example Gx, Gy and Gz can be used in any given predefined combination with a bandwidth-limited RF pulse in order to select a slice at right angles to the vector sum of the gradient combination. The gradient coils 3 can be supplied with power by the respective amplifiers 17, 18, 19 in order to create the respective gradient fields in the x direction, y direction or z direction. Each amplifier 17, 18, 19 can contain a corresponding digital-analog converter, which is controlled by the sequence controller 13 in order to create respective gradient pulses at predefined points in time.

It should be pointed out that the components of the MR system 1 can also be arranged in a way other than that shown in FIG. 1. For example, the gradient coils 3 can be arranged within the bore 5 in a similar way to that shown for the at least one RF coil 4.

The sequence controller 13 can control the creation of RF pulses by an emitter channel 16 of the RF controller 12 and an RF power amplifier 11 of the RF system 4, 11, 12.

It is pointed out that each component of the MR system 1 can contain further elements that are required for its operation, and/or additional elements that provide functions other than those described in the present disclosure.

In order to carry out a disclosed computer-implemented method, MR measurement data that represents an object to be imaged is obtained. Refined MR data is created by a refinement module of a trained MLM 22 being applied to module input data k₀, k₁, k₂, k₃, k_{T} dependent on the MR measurement data. An image reconstruction 21 is created depending on the refined MR data.

In this case, depending on the MR measurement data, optimized MR data is created, in that, by variation of variable image data, a predefined target function is optimized, and the module input data k₀, k₁, k₂, k₃, k_{T} depends on the optimized MR data. As an alternative or in addition, depending on the refined MR data k₁, k₂, k₃, further optimized MR data is created, in that, by variation of variable image data, a further target function is optimized, and the image reconstruction 21 is created depending on the further optimized MR data.

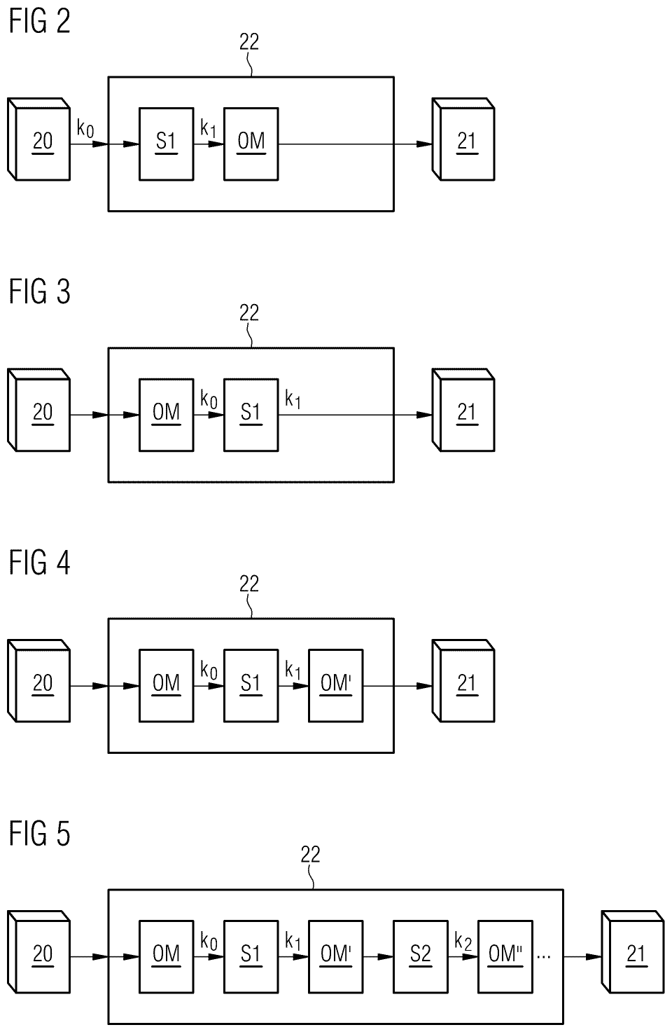

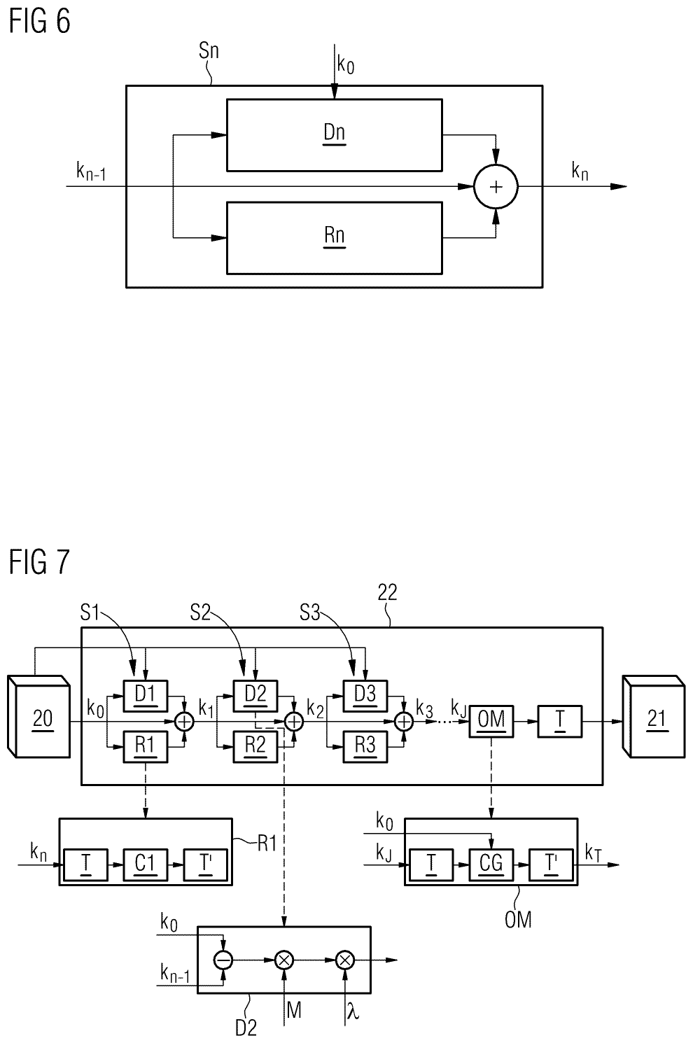

FIG. 2 shows a schematic block diagram of an exemplary form of aspect of a disclosed computer-implemented method for image reconstruction in MR imaging.

In the example of FIG. 1 the MLM 22 has precisely one refinement module S1. The MR measurement data corresponds to the module input data k₀. The MLM 22 has an optimization module OM that, based on the refined MR data k₁, i.e. on the output of the refinement module S1, optimizes a target function by variation of variable image data in order to create optimized MR data. The image reconstruction 21 corresponds for example to the optimized MR data created in this way.

The target function in this case is for example given by

(1)

$${‖ MEx - {k}_{0} ‖}_{2}^{2} + {μ}_{1} {‖ x - {x}_{1} ‖}_{2}^{2} ,$$

wherein x refers to variable image data, E refers to the forward encoding operator, M refers to the masking operator corresponding to a k-space sampling scheme used when creating the MR measurement data, and μ₀ refers to a predetermined regularization parameter. x₁=E^{H}k₁ also applies.

FIG. 3 shows a schematic block diagram of a further exemplary form of aspect of a disclosed computer-implemented method for image reconstruction in MR imaging.

Here too the MLM 22 has precisely one refinement module S1 and one optimization module OM. The optimization module OM here is however not downstream of the refinement module S1 as in FIG. 2, but is upstream of it. The optimization module OM therefore optimizes a target function based on the MR measurement data, in order to create optimized MR data k₀, which is now supplied as module input data k₀ to the refinement module S1. The refined MR data k₁, as output of the refinement module S1, then corresponds for example to the image reconstruction 21.

The target function in this case is for example given by

(2)

$${‖ MEx - {k}_{0} ‖}_{2}^{2} + {μ}_{0} {‖ x ‖}_{2}^{2} ,$$

wherein μ₀ refers to a further predetermined regularization parameter.

In alternate forms of aspects of the disclosure, the target function can also be given by

$${‖ MEx - {k}_{0} ‖}_{2}^{2} + {μ}_{0} {‖ x - {x}_{0} ‖}_{2}^{2}$$

where x₀=E^{H}k₀, in particular when the optimization is not fully carried out until convergence.

FIG. 4 shows a schematic block diagram of a further exemplary form of aspect of a disclosed computer-implemented method for image reconstruction in MR imaging, which is based on the form of aspect of FIG. 3.

Here the MLM has the optimization module OM upstream from the refinement module S1 as well as an optimization module OM′ downstream from the refinement module S1. The refined MR data k₁ is created by optimization of a first target function, as described in relation to FIG. 3. Based on the refined MR data k₂ the optimization module OM′ now optimizes a second target function in order to create further optimized data, which corresponds for example to the image reconstruction 21.

The first target function in this case is for example given by the expression (2) and the second target function by the expression (1).

FIG. 5 shows a schematic block diagram of a further exemplary form of aspect of a disclosed computer-implemented method for image reconstruction in MR imaging, which is based on the form of aspect of FIG. 4.

Here the MLM has a further refinement module S2, which follows the optimization module OM′, as well as an optimization module OM″, which follows the refinement module S2. The optimization module OM optimizes a first target function, which is given in particular by the expression (2), in order to create the optimized MR data k₀. The refinement module S1 is applied to the optimized MR data k₀ created by means of the optimization module OM, in order to create refined MR data k₁. The optimization module OM′ optimizes a second target function, which is in particular given by the expression (1), and the refinement module S2 is applied to the optimized MR data created by means of the optimization module OM′, in order to create refined MR data k₂. The optimization module OM″ optimizes a third target function, which in particular is given by the expression

(3)

$$‖ MEx - {k}_{0} {‖}_{2}^{2} + {μ}_{2} {‖ x - {x}_{2} ‖}_{2}^{2} ,$$

wherein μ₂ refers to a further predetermined regularization parameter. x₂=E^{H}k₂ further applies. The output of the optimization module OM″ then corresponds for example to the image reconstruction 21.

In further forms of aspects of the disclosure, the principle shown in FIG. 5 can be expanded to a plurality of refinement modules, wherein precisely one of the optimization modules OM, OM′, OM″ is arranged before and after each refinement module. It is however not absolutely necessary for an optimization module OM, OM′, OM″ to be arranged before and after each refinement module. Instead, in some forms of aspect, an optimization module OM, OM′, OM″ can also be provided only before and/or after one of the refinement modules or for example before and/or after each second refinement module or for example before and/or after each third refinement module and so forth. What is common to all forms of aspect however is that the MLM 22 has at least one refinement module and an optimization module OM, OM′, OM″ arranged before this or after this.

FIG. shows a schematic block diagram of a representative refinement module Sn for describing an exemplary structure of the refinement modules. All refinement modules of the MLM 22 can be structured in this way.

The refinement module Sn for example contains a data consistency module Dn and an ANN module Rn. The ANN module Rn can for example, as shown in FIG. 7, have a transformation module T of a CNN Cn, which can be a U-Net for example, followed by a back-transformation module T′. The ANN module Rn thus receives input data kₙ₋₁ of the MR measurement data k₀ or refined MR data created by a preceding refinement module or optimized MR data created by a preceding optimization module. The transformation module T applies the conjugate forward encoding operator to this, in order to transfer the MR data kₙ₋₁ into the image space. The CNN Cn is then applied to the transformed MR data and the back-transformation module T′ applies the forward encoding operator to the output of the CNN Cn in order to transform it back into the k-space.

The data consistency module Dn likewise receives the input data kₙ₋₁ and subtracts it from the MR measurement data k₀. The masking operator M is applied to the result for example, in order to take account of the k-space sampling scheme used. The result thereof is for example multiplied by a regularization parameter A.

Then a sum or weighted sum of the MR measurement data k₀ of the output of the ANN module Rn and of the output of the data consistency module Dn is calculated in order to create the refined MR data kₙ.

FIG. 7 shows a schematic block diagram of a further exemplary form of aspect of a disclosed computer-implemented method for image reconstruction in MR imaging.

Here the MLM 22 has a number J of refinement modules, which are each structured for example as explained in relation to FIG. The MLM 22 here has precisely one optimization module OM, which is arranged after the last refinement module. The optimization module OM is followed by a further transformation T with the conjugate forward encoding operator. This last transformation T can however also be integrated into the optimization module OM.

The optimization module OM thus receives the MR measurement data k₀ as well as the refined MR data k_{J} of the last refinement module. It applies the transformation T with the conjugate forward encoding operator to the refined MR data k_{J}, then carries out an optimization of a target function, in particular by application of a CG method, for example in a few iterations, for example 10 iterations and, based on the optimization result, carries out the back-transformation T′ with the forward encoding operator. The target function in this case is for example given by

$${‖ MEx - {k}_{0} ‖}_{2}^{2} + {μ}_{J} {‖ x - {x}_{J} ‖}_{2}^{2} ,$$

where x_{J}=E^{H}k_{J}.

The data consistency and the reconstruction quality can be enhanced by the integration of the optimization modules OM, OM′, OM″ into the architecture of the MLM 22.

The CG method can be used in particular. CG optimization can be undertaken in various forms of aspect once at the end of the MLM 22, i.e. after the last cascade, once at the start of the MLM 22, i.e. before the first cascade, and/or once or a number of times between the individual cascades, such as after each mth cascade. The current estimation is for example the output of the preceding cascade. This means that the solution to the optimization problem is regulated so that it lies close to this current estimation. The CG method can be initialized in various ways, for example by the current reconstruction estimate, by the Fourier transform of the MR measurement data, or set to random values or zeroes. Initialization with zeros or random values in particular enables local minima of the optimization problem to be overcome.

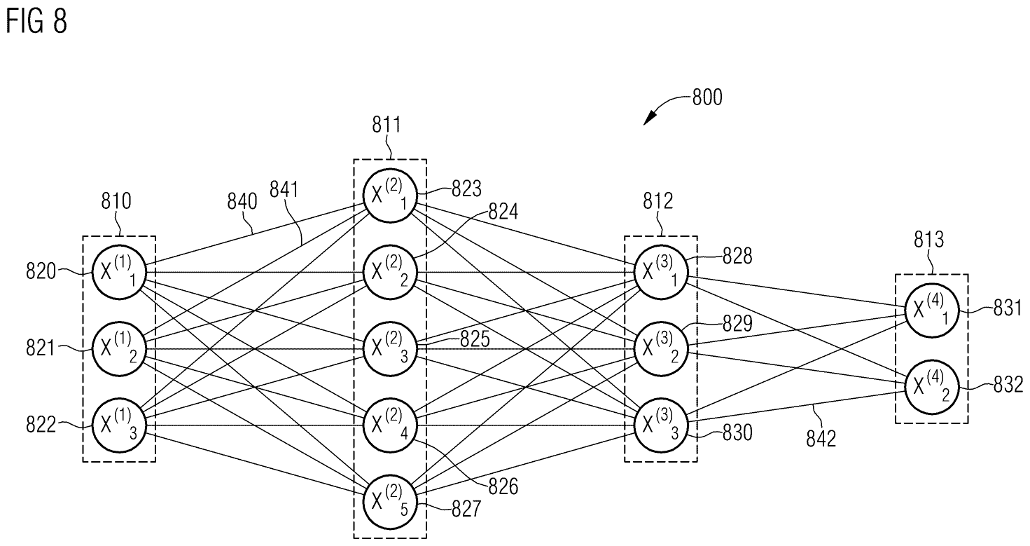

FIG. 8 shows a form of aspect of an artificial neural network, ANN, 800. The ANN 800 comprises nodes 820, . . . , 832 and edges 840, . . . , 842, wherein each edge 840, . . . , 842 is a directed connection from a first node 820, . . . , 832 to a second node 820, . . . , 832. In general, the first node 820, . . . , 832 and the second node 820, . . . , 832 are different nodes 820, . . . , 832. It is however also possible for the first node 820, . . . , 832 and the second node 820, . . . , 832 to be identical. In FIG. 8 for example the edge 840 is a directed connection from the node 820 to the node 823 and the edge 842 is a directed connection from the node 830 to the node 832. An edge 840, . . . , 842 from a first node 820, . . . , 832 to a second node 820, . . . , 832 is also referred to as an ingoing edge for the second node 820, . . . , 832 and as an outgoing edge for the first node 820, . . . , 832.

In this example the nodes 820, . . . , 832 of the ANN 800 can be arranged in layers 810, . . . , 813, wherein the layers can have an intrinsic order, which is introduced by the edges 840, . . . , 842 between the nodes 820, . . . , 832. In particular the edges 840, . . . , 842 can only exist between neighboring layers of nodes. In the example shown there is an input layer 810, which only consists of the nodes 820, . . . , 822 without ingoing edges, an output layer 813, which only consists of the nodes 831, 832 without outgoing edges, and hidden layers 811, 812 between the input layer 810 and the output layer 813. In general, any number of hidden layers 811, 812 can be chosen. With a multilayer perceptron, MLP, this number is at least one. The number of nodes 820, . . . , 822 within the input layer 810 relates as a rule to the number of input values of the artificial neural network 800, and the number of nodes 831, 832 within the output layer 813 relates as a rule to the number of output values of the artificial neural network 800.

In particular each node 820, . . . , 832 of the artificial neural network 800 can be allocated a real number as its value. In this case x⁽ⁿ⁾ᵢ refers to the value of the ith node 820, . . . , 832 of the nth layer 810, . . . , 813. The values of the nodes 820, . . . , 822 of the input layer 810 correspond to the input values of the artificial neural network 800. The values of the nodes 831, 832 of the output layer 813 correspond to the output value of the artificial neural network 800. Moreover, each edge 840, . . . , 842 can have a weight that is a real number. In particular the weight is a real number within the interval [−1, 1] or within the interval [0, 1]. In this case w^{(m,n)}_{i,j} refers to the weight of the edge between the ith node 820, . . . , 832 of the mth layer 810, . . . , 813 and the jth node 820, . . . , 832 of the nth layer 810, . . . , 813. Moreover, the abbreviation w⁽ⁿ⁾_{i,j} is defined for the weight w^{(n,n+1)}_{i,j}. In order to calculate the output values of the neural network 800, the input values in particular are propagated through the neural network 800. In particular the values of the nodes 820, . . . , 832 of the (n+1)th layer 810, . . . , 813 can be calculated based on the values of the nodes 820, . . . , 832 of the nth layer 810, . . . , 813 as

$${x}_{j}^{( n + 1 )} = f ( {\sum }_{i} {x}_{i}^{( n )} {w}_{i , j}^{( n )} ) .$$

In this equation the function f is referred to as the transmission function or activation function. Known transmission functions are step functions, Sigmoid functions, for example the logistical function, the generalized logistical function, the hyperbolic tangent, the arc tangent function, the error function, the Smoothstep function or rectifier functions. The transmission function is primarily used for normalization. In particular the values are propagated layer-by-layer through the neural network 800, wherein the values of the input layer 810 are given by the input of the neural network 800, wherein the values of the first hidden layer 811 can be calculated on the basis of the values of the input layer 810 of the neural network 800, wherein the values of the second hidden layer 812 can be calculated on the basis of the values of the first hidden layer 811, and so forth.

In order to define the values w^{(m,n)}_{i,j} for the edges, the neural network 800 must be trained with training data. The training data in particular comprises training input data and training output data (referred to as tᵢ). In a training step the neural network 800 is applied to the training input data in order to create calculated output data. In particular the training data and the calculated output data comprises a number of values, which corresponds to the number of nodes of the output layer. In particular a comparison between the calculated output data and the training data is used in order to adapt the weights within the neural network 800 recursively (backpropagation algorithm). In particular the weights are changed in accordance with the following formula:

$${w}_{i , j}^{′ ( n )} = {w}_{i , j}^{( n )} - γ {δ}_{j}^{( n )} {x}_{i}^{( n )} ,$$

wherein γ is a predefined learning rate, and the numbers δ⁽ⁿ⁾ⱼ can be calculated recursively as

$${δ}_{j}^{( n )} = ( {\sum }_{k} {δ}_{k}^{( n + 1 )} {w}_{j , k}^{( n + 1 )} ) {f}^{′} ( {x}_{i}^{( n )} {w}_{i , j}^{( n )} )$$

based on δ⁽ⁿ⁺¹⁾ⱼ, when the (n+1)th layer is not the output layer 813, and

$${δ}_{j}^{( n )} = ( {x}_{j}^{( n + 1 )} - {t}_{j}^{( n + 1 )} ) {f}^{′} ( {x}_{i}^{( n )} {w}_{i , j}^{( n )} ) ,$$

when the (n+1)th layer is the output layer 813, wherein f′ is the first derivation of the activation function, and t⁽ⁿ⁺¹⁾ⱼ is the comparison training value for the jth node of the output layer 813.

A convolutional neural network, CNN is an ANN, which in at least one of its layers uses a convolution operation instead of a general matrix multiplication. These layers are referred to as convolution layers. In particular a convolution layer carries out a point product of one or more convolution kernels with the input data of the convolution layer, wherein the entries of the one or more convolution kernels are parameters or weights, which can be adapted by training. In particular the inner Frobenius product and the ReLU activation function can be used. A convolutional neural network can comprise additional layers, for example pooling layers, completely connected layers and/or normalization layers.

The use of convolutional neural networks enables the input to be processed very efficiently, since a convolution operation, which is based on various kernels, can extract various image features, so that through the adaptation of the weights of the convolution kernel the relevant image features can be determined during the training. Moreover, fewer parameters have to be trained because of the shared use of the weights in the convolution kernels, which prevents an overfitting in the training phase and makes a faster training or more layers in the network possible, whereby the performance of the network is improved.

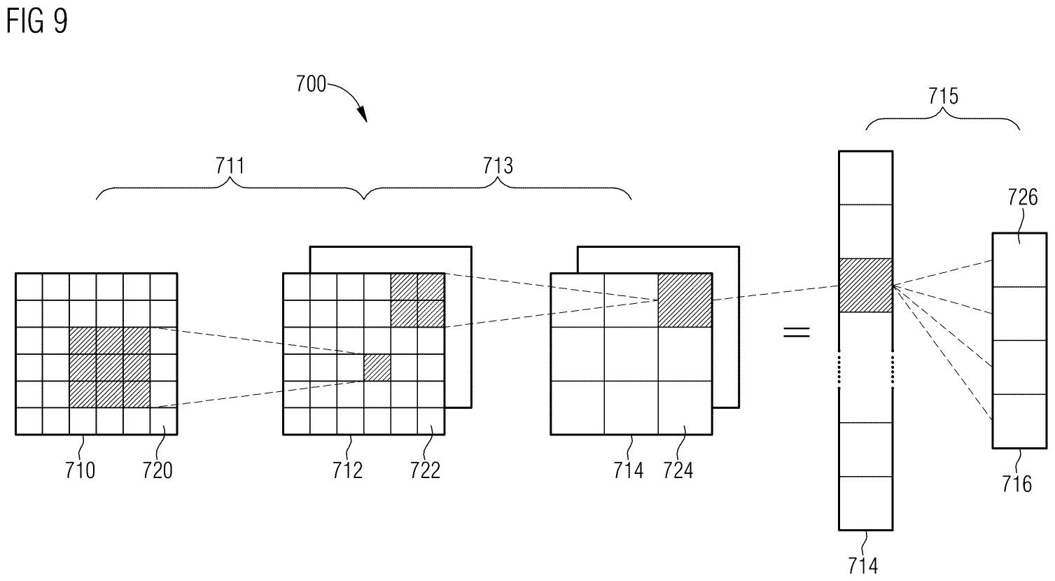

FIG. 9 shows an exemplary form of aspect of a convolutional neural network 700. In the form of aspect shown the convolutional neural network 700 comprises an input layer 710, a convolution layer 711, a pooling layer 713, a completely connected layer 714 and an output node layer 716 as well as hidden node layers 712, 714. As an alternative the convolutional neural network 700 can also comprise a number of convolution layers 711, a number of pooling layers 713 and/or a number of connected layers 715 as well as other types of layers. The order of the layers can be selected at random, as a rule completely connected layers 715 are used as the last layers before the output layer 716.

In particular, in a convolutional neural network 700 the nodes 720, 722, 724 of a node layer 710, 712, 714 are considered as a d-dimensional matrix or as a d-dimensional image. In particular in the two-dimensional case the value of the node 720, 722, 724 indexed with i and j in the nth node layer 710, 712, 714 is referred to as x(n)[i, j]. The arrangement of the nodes 720, 722, 724 of a node layer 710, 712, 714 however has no influence as such on the calculations that are carried out within the convolutional neural network 700, since these are given solely by the structure and the weights of the edges.

A convolution layer 711 is a connection layer between a front node layer 710 with node values x(n−1) and a rear node layer 712 with node values x(n). A convolution layer 711 is in particular characterized by the structure and the weights of the ingoing edges, which form a convolution operation on the basis of a specific number of kernels. In particular the structure and the weights of the edges of the convolution layer 711 are selected so that the values x(n) of the nodes 722 of the rear node layer 712 are defined as a convolution x(n)=K*x(n−1) on the basis of the values x(n−1) of the nodes 720 of the front node layer 710, wherein the convolution * in the two-dimensional case is defined as

$${x}^{( n )} [ i , j ] = ( K * {x}^{( n - 1 )} ) [ i , j ] = {\sum }_{{i}^{′}} {\sum }_{{j}^{′}} K [ {i}^{′} , {j}^{′} ] \cdot {x}^{( n - 1 )} [ i - {i}^{′} , j - {j}^{′} ] .$$

In this case the kernel K is a d-dimensional matrix, in the present example a two-dimensional matrix, which as a rule is small compared to the number of nodes 720, 722, for example a 3×3 matrix or a 5×5 matrix. This means in particular that the weights of the edges in the convolution layer 711 are not independent, but are selected so that they produce the said convolution equation. In particular for a kernel that is a 3×3 matrix, there are only 9 independent weights, wherein each entry of the kernel matrix corresponds to an independent weight, regardless of the number of nodes 720, 722 in the front node layer 710 and the rear node layer 712.

In general, convolutional neural networks 700 use node layers 710, 712, 714 with a plurality of channels, in particular due to the use of a plurality of kernels in the convolution layers 711. In these cases, the node layers can be regarded as (d+1)-dimensional matrixes, wherein the first dimension indexes the channels. The effect of a convolution layer 711 is then defined, in a two-dimensional example, as

$${x}_{b}^{( n )} [ i , j ] = {\sum }_{a} ( {K}_{a , b} * {x}_{a}^{( n - 1 )} [ i , j ] = {\sum }_{a} {\sum }_{{i}^{′}} {\sum }_{{j}^{′}} {K}_{a , b} [ {i}^{′} , {j}^{′} ] \cdot {x}_{a}^{( n - 1 )} [ i - {i}^{′} , j - {j}^{′} ] ,$$

wherein xₐ⁽ⁿ⁾ corresponds to the ath channel of the preceding node layer 710, x_{b}⁽ⁿ⁾ corresponds to the bth channel of the following node layer 712 and K_{a,b} corresponds to one of the kernels. When a convolution layer 711 acts on a preceding node layer 710 with A channels and outputs a following node layer 712 with B channels, there are A·B independent d-dimensional kernels K_{a,b}.

In general, in convolutional neural networks 700 activation functions can be used. In this form of aspects of the disclosure, a ReLU (rectified linear unit) is used, where R(z)=max(0, z), so that the effect of the convolution layer 711 in the two-dimensional example is

$${x}_{b}^{( n )} [ i , j ] = R ( {\sum }_{a} ( {K}_{a , b} * {x}_{a}^{( n - 1 )} [ i , j ] ) = R ( {\sum }_{a} {\sum }_{{i}^{′}} {\sum }_{{j}^{′}} {K}_{a , b} [ {i}^{′} , {j}^{′} ] \cdot {x}_{a}^{( n - 1 )} [ i - {i}^{′} , j - {j}^{′} ] ) .$$

It is also possible to use other activation functions, for example ELU (exponential linear unit), LeakyReLU, Sigmoid, Tanh or SoftMax.

In the form of aspect shown the input layer 710 contains 36 nodes 720, which are arranged in a two-dimensional×6 matrix. The first hidden node layer 712 includes 72 nodes 722, which are arranged as two-dimensional×6 matrixes, wherein each of the two matrixes is the result of a convolution of the values of the input layer with a 3×3 kernel within the convolution layer 711. Equivalent to this the node 722 of the first hidden node layer 712 can be interpreted as a three-dimensional 2×6×6 matrix, wherein the first dimension corresponds to the channel dimension.

An advantage of the use of convolution layers 711 consists of a spatially local correlation of the input data being utilized, in that a local connectivity pattern is forced between the nodes of neighboring layers, in particular in that each node is only connected to a small range of the nodes of the preceding layer.

A pooling layer 713 is a connecting layer between a preceding node layer 712 with node values x(n−1) and a following node layer 714 with node values x(n). A pooling layer 713 can be characterized in particular by the structure and the weights of the edges and the activation function, which form a pooling operation on the basis of a non-linear pooling function f. For example, in the two-dimensional case the values x(n) of the nodes 724 of the following node layer 714 are calculated based on the values x(n−1) of the nodes 722 of the anterior node layer 712 as follows

$${x}_{b}^{( n )} [ i , j ] = f ( {x}_{b}^{( n - 1 )} [ {id}_{1} , {jd}_{2} ] , … , {x}_{b}^{( n - 1 )} [ ( i + 1 ) {d}_{1} - 1 , ( j + 1 ) {d}_{2} - 1 ] ) .$$

In other words, through the use of a pooling layer 713, the number of nodes 722, 724 is reduced by a number d1−d2 of neighboring nodes 722 in the preceding node layer 712 being replaced by a single node 722 in the following node layer 714, which is calculated as a function of the values of the said number of neighboring nodes. The pooling function f can in particular be the max function, the average value or the L2 norm. In particular in a pooling layer 713 the weights of the ingoing edges are fixed and are not changed by the training.

The advantage of using a pooling layer 713 is that the number of nodes 722, 724 and the number of parameters is reduced. This leads to a reduction in the calculation effort in the network and to a checking of the overfitting.

In the form of aspects of the disclosure shown the pooling layer 713 is a max pooling layer, in which four neighboring nodes are replaced by just one node, wherein the value is the maximum of the values of the four neighboring nodes. The max pooling is applied to each d-dimensional matrix of the preceding layer. In this form of aspects of the disclosure, the max pooling is applied to each of the two-dimensional matrixes, whereby the number of nodes is reduced from 72 to 18.

In general, the last layers of a convolutional neural network 700 can be completely connected layers 715. A completely connected layer 715 is a connecting layer between a preceding node layer 714 and a following node layer 716. A completely connected layer 713 can be characterized by a majority of, in particular all, edges between the nodes 714 of the preceding node layer 714 and the nodes 716 of the following node layer being present, and wherein the weight of each of these edges can be adapted individually.

In this form of aspects of the disclosure, the nodes 724 of the front node layer 714 of the completely connected layer 715 are shown both as two-dimensional matrixes and also additionally as non-related nodes, which are shown as a line of nodes, wherein the number of nodes has been reduced so that they can be better illustrated. This process is also referred to as flattening. In this form of aspects of the disclosure, the number of nodes 726 in the following node layer 716 of the completely connected layer 715 is less than the number of nodes 724 in the preceding node layer 714. As an alternative the number of nodes 726 can also be the same or greater.

Moreover, in this form of aspect the SoftMax activation function is used within the completely connected layer 715. Through the application of the SoftMax function the sum of the values of all nodes 726 of the output layer 716 is equal to 1, and all values of all nodes 726 of the output layer 716 are real numbers between 0 and 1. When in particular the convolutional neural network 700 is used for categorization of input data, the values of the output layer 716 can be interpreted as the probability that the input data falls into one of the various categories.

In particular convolutional neural networks 700 can be trained based on the backpropagation algorithm. Regularization methods can be used in order to prevent an overfitting, for example the leaving out of nodes 720, . . . , 724, stochastic pooling, the use of artificial data, weight descent based on the L1 or L2 norm or max norm restrictions.

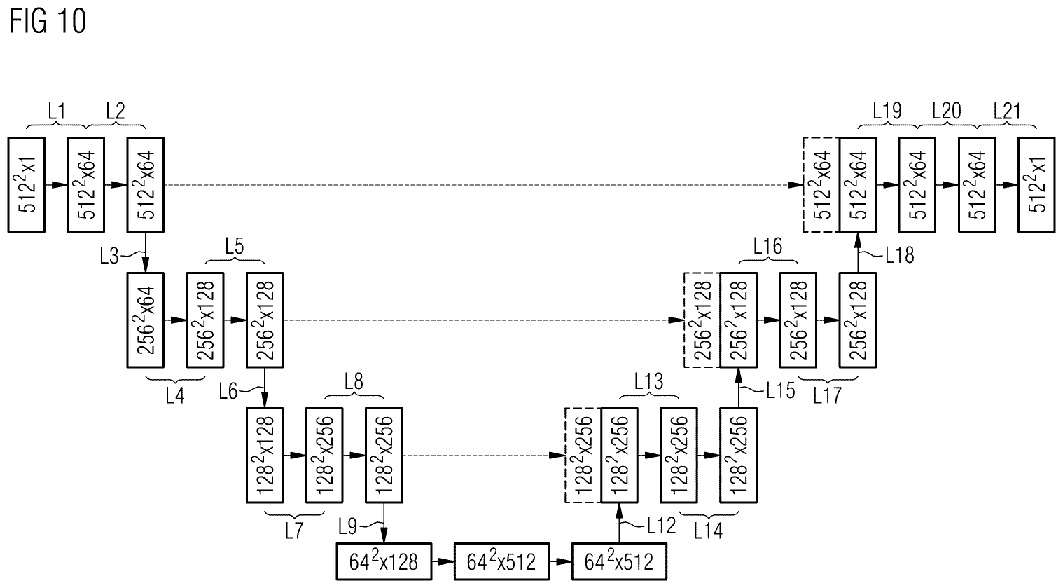

Shown schematically in FIG. 10 is a CNN with a U-Net structure. In the example shown the input data for the CNN is a two-dimensional medical image with 512×512 pixels, wherein each pixel includes an intensity value. The CNN includes convolution layers, which are shown by solid, horizontal arrows, pooling layers, which are shown by solid arrows pointing downward, and upsampling layers, which are shown by solid arrows pointing upward. The number of the respective nodes is specified in the boxes. Within the U-Net structure first of all the input images are downsampled, in particular by making the images smaller and increasing the number of channels. Subsequently they are upsampled, in particular by making the images larger and reducing the number of channels, in order to create a transformed image.

All except the last convolution layers L1, L2, L4, L5, L7, L8, L10, L11, L13, L14, L16, L17, L19, L20 use 3×3 kernels with a padding of 1, the ReLU activation function and a number of filters or convolutional kernels, which corresponds to the channels of the respective node layers, as shown in FIG. 10. The last convolution layer uses a 1×1 kernel without padding and the ReLU activation function.

The pooling layers L3, L6, L9 are max pooling layers, which replace four neighboring nodes by just one node, wherein the value is the maximum of the values of the four neighboring nodes. The upsampling layers L12, L15, L18 are transposed convolution layers with 3×3 kernels and stride 2, whereby the number of nodes is effectively quadrupled. The dashed horizontal arrows correspond to chaining operations, in which the output of one convolution layer L2, L5, L8 of the downsampling branch of the U-Net structure is used as additional inputs for a convolution layer L13, L16, L19 of the upsampling branch of the U-Net structure. This additional input data is treated as additional channels in the input node layer for the convolution layer L13, L16, L19 of the upsampling branch.

A database with 500 first medical images has been used for training the CNN, wherein the respective segmentation mask has been created based on annotations of radiological experts. In particular the experts determined a segmentation mask for a structure of interest for each of the 500 first medical images, wherein the pixels that correspond to the structure of interest have been assigned a value of 1 and the pixels that do not correspond to the structure of interest have been assigned a value of 0. The database has been divided into training data (320 datasets), validation data (80 datasets) and test data (100 datasets). The backpropagation algorithm has been used for training the CNN, based on a binary cross entropy cost function

$$L ( x , y ) = {\sum }_{i} {\sum }_{j} BCE ( y [ i , j ] , M ( x ) [ i , j ] )$$

$$where$$

$$BCE ( a , b ) := - a log ( b ) ( b ) - ( 1 - a ) log ( 1 - b ) ,$$

wherein x refers to a medical image, y determines the corresponding segmentation mask that has been created by the radiology experts, and M(x) refers to the result of the application of the CNN to the first medical input image x. As an alternative other cost functions such as weighted binary cross entropy, focal loss or dice loss could also be used.

Based on the validation set of 80 datasets and the corresponding annotations, the model with the best performance has been selected from a number of machine learning models (with different hyperparameters, for example number of layers, size and number of kernels, padding et cetera). The specificity and the sensitivity have been determined based on the test set, which includes 100 datasets and the corresponding annotations.

Independent of the grammatical term usage of a specific person-related term, individuals with male, female or other gender identities should be included within the term.

1. A computer-implemented method for image reconstruction in magnetic resonance (MR) imaging, comprising:
obtaining MR measurement data that represents an imaged object;
creating refined MR data by a refinement module of a trained machine learning model (MLM) applied to module input data dependent on the MR measurement data;
creating an image reconstruction depending on the refined MR data; and
wherein:
depending on the MR measurement data, creating optimized MR data such that, by variation of variable image data, a predefined target function is optimized, and the module input data depends on the optimized MR data; and/or
depending on the refined MR data, creating further optimized MR data such that, by variation of variable image data, a further target function is optimized, and the image reconstruction is created depending on the further optimized MR data.

2. The computer-implemented method as claimed in claim 1, further comprising:
using a method of conjugate gradients in order to optimize the target function and/or to optimize the further target function.

3. The computer-implemented method as claimed in claim 1, wherein the refinement module includes a convolutional artificial neural network (CNN).

4. The computer-implemented method as claimed in claim 3, wherein application of the refinement module to the module input data includes a transformation of the module input data from a k-space into an image space and an application of the CNN to the transformed module input data.

5. The computer-implemented method as claimed in claim 4, wherein the refined MR data is created depending on a sum or weighted sum of an output of the CNN and a data consistency term, wherein the data consistency term depends on a deviation of the module input data from the MR measurement data.

6. The computer-implemented method as claimed in claim 4, wherein the application of the refinement module to the module input data includes a back-transformation of an output of the CNN into the k-space and the refined MR data is determined depending on a sum or weighted sum of the back-transformed output of the CNN and a data consistency term, wherein the data consistency term depends on a deviation of the module input data from the MR measurement data.

7. The computer-implemented method as claimed in claim 1, wherein the target function is represented by:
$${‖ MEx - {k}_{0} ‖}_{2}^{2} + {μ}_{0} {‖ x ‖}_{2}^{2} ,$$
wherein x refers to the variable image data, E refers to a forward encoding operator, M refers to a masking operator corresponding to a k-space sampling scheme used for creation of the MR measurement data, and μ₀ refers to a predetermined regularization parameter.

8. The computer-implemented method as claimed in claim 1, wherein the further target function depends on a deviation of the variable image data from refined image data, which is represented by:
xₙ=E^{H}kₘ,
wherein kₙ refers to the refined MR data and E^{H} refers to a conjugate forward encoding operator.

9. The computer-implemented method as claimed in claim 8, wherein the further target function is represented by:
$${‖ MEx - {k}_{0} ‖}_{2}^{2} + {μ}_{n} {‖ x - {x}_{n} ‖}_{2}^{2} ,$$
wherein x refers to the variable image data, E refers to the forward encoding operator, M refers to a masking operator corresponding to a k-space sampling scheme used for creation of the MR measurement data, and μₙ refers to a predetermined further regularization parameter.

10. The computer-implemented method as claimed in claim 4, wherein the MR measurement data corresponds to data that has been measured in accordance with at least two receive coil channels.

11. The computer-implemented method as claimed in claim 1,
wherein the MLM contains two or more consecutive stages, wherein one stage of the two or more stages contains the refinement module; and
wherein:
the MLM contains an optimization module, which is adapted, depending on the MR measurement data, to create the optimized MR data and, by variation of the variable image data, to optimize the target function; and/or
the MLM contains a further optimization module, which is adapted, depending on the refined MR data, to create the further optimized MR data and, by variation of the variable image data, to optimize the further target function.

12. A computer-implemented training method for training a machine learning model (MLM) for use in a computer-implemented method for image reconstruction in magnetic resonance imaging as claimed in claim 1, comprising:
obtaining MR training data and creating refined MR training data by a refinement module of the MLM being applied to module training input data dependent on the MR training data;
evaluating a predetermined loss function depending on the MR training data and the refined MR training data, and updating the MLM depending on a result of the evaluation of the loss function; and
creating optimized MR training data depending on the MR training data such that, by variation of variable image data, the target function is optimized, and the module training input data depends on the optimized MR training data, and/or, depending on the refined MR training data, creating further optimized MR training data such that, by variation of variable image data, the further target function is optimized, and the loss function depends on the further optimized MR training data.

13. The computer-implemented training method as claimed in claim 12, wherein:
a training image reconstruction is created depending on the refined MR training data, completely sampled MR data is obtained and the MR training data is created depending on the completely sampled MR data in accordance with a predetermined undersampling scheme, a ground truth image reconstruction is created based on the completely sampled MR data, and the loss function depends on a deviation of the training image reconstruction from the ground truth image reconstruction; or
the MR training data corresponds to undersampled MR data in accordance with a predetermined undersampling scheme and the MLM is trained by self-supervised learning.

14. A data processing system having at least one data processing device, which is adapted to carry out a computer-implemented method for image reconstruction as claimed in claim 1.

15. A non-transitory computer program product having commands that, when executed by a data processing system, cause the data processing system to carry out a computer-implemented method for image reconstruction as claimed in claim 1.
